(19) United States
(12) Patent Application Publication
(10) Pub. No.: US 2014/0159802 A1
(43) Pub. Date: Jun. 12, 2014

(54) NON-CONTACT TYPE SWITCH CONTROL DEVICE AND CONTROL METHOD THEREOF

(71) Applicant: ANALOGTEK CORP., Taipei City (TW)

(72) Inventor: Chu-Chiao YU, Taipei City (TW)

(73) Assignee: ANALOGTEK CORP., Taipei City (TW)

(21) Appl. No.: 13/743,014

(22) Filed: Jan. 16, 2013

(30) Foreign Application Priority Data
Dec. 11, 2012 (TW) 101146587

(51) Int. Cl. H03K 17/18

(52) U.S. Cl. CPC H03K 17/18
USPC 327/517

(57) ABSTRACT

A non-contact type switch control device and control method thereof, comprising: a control panel, on which is provided with a plurality of indicator units; a plurality of sensor elements, disposed on said control panel, each said sensor element detects distance information of an object; and a control circuit, connected electrically to said indicator units and said sensor elements, to receive and determine said distance information, then it finds a minimum value of said distance information, and determine if said value is less than a threshold value, then record number of times said minimum value less than said threshold value, and determine if said number is greater than a preset value, and finally, activate corresponding indication and perform control of a controlled unit. Based on device and method mentioned above, a user does not have to touch a switch, to achieve triggering of said sensor element.

### BACKGROUND OF THE INVENTION

1. Field of the Invention

The present invention relates to a switch control device, and in particular to a non-contact type switch control device and a control method thereof.

2. The Prior Arts

In general, an ordinary switch, such as a push button of an elevator, is a contact type switch. The user has to use his finger to press down the push button to activate the elevator to the floor desired to reach. However, for this contact type switch utilized in public places, it is liable to become a medium of contagious diseases, such that the bacteria are transmitted from a user to another user through the contact type switch, to harm the health of the user.

By way of example, for the patients in a hospital, quite a lot of articles can be sources of contagious diseases through contact by the patients. Wherein, the push button of an elevator in a hospital tends to be a possible medium for contagious disease. Therefore, for the safe control of contagious disease, medic care personnel are strictly forbidden to wear working gloves while pressing down the push button of an elevator, to avoid contagion of diseases through contact. So, for the medic care personnel taking a ride in an elevator, he has to take off his gloves to press down the push button, to cause quite inconvenience. As such, this constitutes a public hygiene problem, that has to be solved for people working in hospitals or other public places.

In addition, for an ordinary contact type push button, its sensitivity tends to deteriorate gradually due to long period of usage, such that it has to be replaced after a certain period of time to keep its operational sensitivity, hereby causing waste of material and quite inconvenience.

Therefore, presently, the design and performance of the contact type switch is not quite satisfactory, and it has much room for improvement.

### SUMMARY OF THE INVENTION

In view of the problems and shortcomings of the prior art, the present invention provides a non-contact type switch control device and a control method thereof to overcome the shortcomings and drawbacks of the prior art.

A major objective of the present invention is to provide a non-contact type switch control device and a control method thereof. Its design concept is to use sensor element and control circuit to detect movement of objects, to calculate the distance information of the object, and to determine its minimum value. Therefore, when it is used in elevator control or TV station selection, the user does not have to make actual contact to trigger the sensor element. As such, it can solve the problem for people working in public places liable to get contagious disease through contact, and it can also solve the problem of sensitivity deterioration of contact type switch due to long period of usage and pressing.

Another objective of the present invention is to provide a non-contact type switch control device and a control method thereof. Wherein, indicator units and sensor elements are arranged into a sensor matrix, such that the control circuit receives the signal sent back from each sensor element. Then, it activates the corresponding indicator unit after processing and determining the signal, to avoid the error of triggering a plurality of sensor elements at the same time.

In order to achieve the objective mentioned above, the present invention provides a non-contact type switch control device, including a control panel, a plurality of sensor elements, and a control circuit. Wherein, a plurality of indicator units and sensor elements are disposed on the control panel, such that each sensor element is able to detect distance information of an object. The control circuit is connected electrically to the indicator unit and sensor element, and upon receiving and determining the distance information, it sends out a control signal to the corresponding indicator unit, to display the related indication.

Moreover, the present invention provides a non-contact type switch control method, including the following steps: detect distance information of an object, to find a minimum value of the distance information, and then determine if the minimum value is less than a threshold value. If the answer is negative, return to the step of detecting the distance information of the object. Otherwise, count and record the number of times the minimum value is less than a threshold value. Then, determine if this number is greater than a preset value. If the answer is negative, return to the step of detecting the distance information of the object. Otherwise, activate the corresponding indication.

Furthermore, the present invention provides a non-contact type switch control method, including the following steps. Detect distance information of an object, to find the distance information less than the threshold value. Count and record the number of times the distance information fulfilling the threshold value, and set the number of times that the distance information not fulfilling the threshold value to zero. Determine if the number of times the distance information consecutively fulfilling the threshold value is greater than a preset value. In case the answer is negative, then return to the step of detecting the distance information of the object. Otherwise, activate the corresponding indication, and set the number of times of recording the distance information to zero.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

The related drawings in connection with the detailed descriptions of the present invention to be made later are described briefly as follows, in which:

FIG. 1 is a block diagram of a non-contact type switch control device according to the present invention;

FIG. 2 is a schematic diagram of a control panel having indicator units and sensor elements according to the present invention;

FIG. 3 is a flowchart of the steps of a non-contact type switch control method according to a first embodiment of the present invention;

FIG. 4 is a flowchart of the steps of a non-contact type switch control method according to a second embodiment of the present invention;

FIG. 5 is a flowchart of the steps of a non-contact type switch control method according to a third embodiment of the present invention; and

FIG. 6 is a flowchart of the steps of a non-contact type switch control method according to a fourth embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

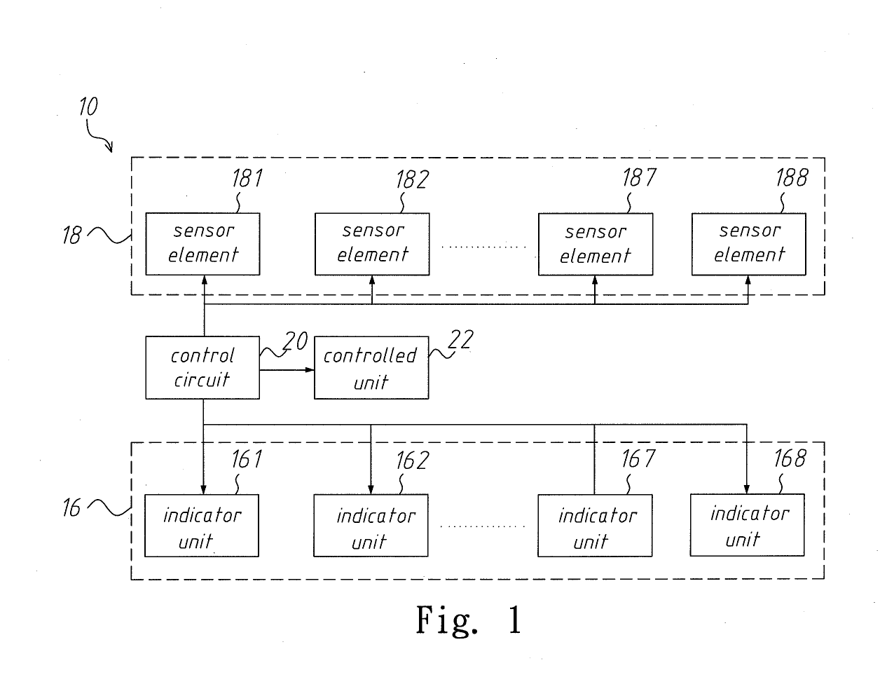

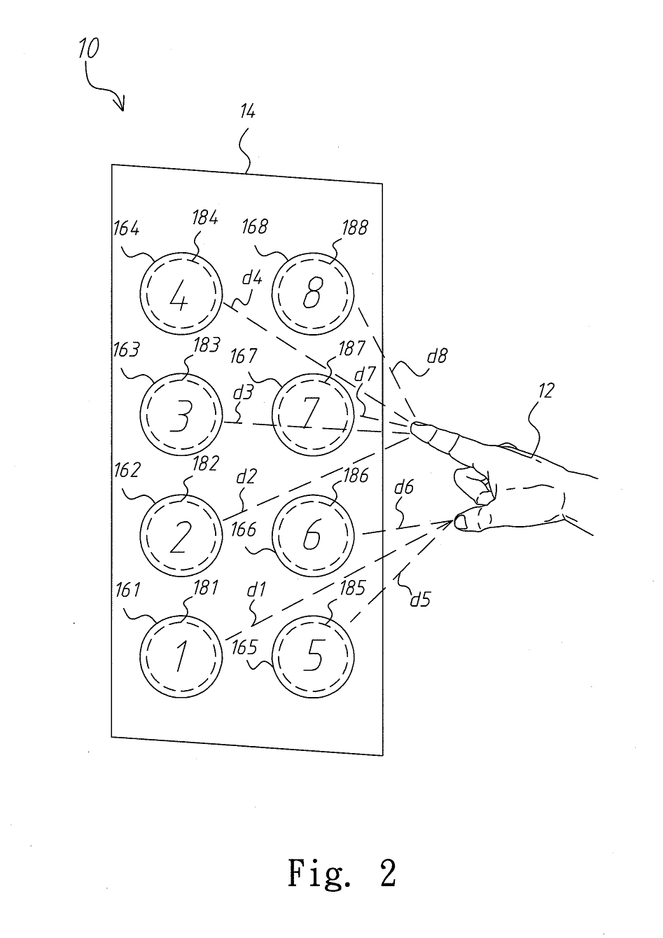

Refer to FIGS. 1 and 2 respectively for a block diagram of a non-contact type switch control device according to the present invention; and a schematic diagram of a control panel having indicator units and sensor elements according to the present invention.

As shown in FIGS. 1 and 2, the present invention discloses a non-contact type switch control device 10 to detect one or more objects 12. The non-contact type switch control device 10 includes: a control panel 14, a plurality of sensor elements 18, and a control circuit 20. Wherein, the control panel 14 is provided with a plurality of indicator units 16, in sequence number 161˜168, and a plurality of sensor elements 18, in sequence number 181˜188. Each sensor elements 18 is able to detect the respective distance information d1˜d8 of an object 12. The control circuit 20 is connected electrically to the plurality of indicator units 161˜168, a plurality of sensor elements 181˜188, and a controlled unit 22, to receive and determine the distance information d1˜d8, and transmit a control signal to the corresponding indicator units 161˜168, so as to display the related indications. The control circuit 20 is able to control the actions of the controlled unit 22.

Since herein, a non-contact type switch control device 10 utilized in elevator is taken as an example for explanation, therefore the controlled unit 22 is a motor, and the object 12 is finger or palm of a person. The indictor units 161˜168 and sensor elements 181˜488 can be modularized onto the control panel 14, while the indictor units 161˜468 are located in corresponding positions to the sensor elements 181˜188.

In addition, in the non-contact type switch control device 10, the indictor units 161˜468 and the sensor elements 181˜188 can be arranged into a sensor matrix. As shown in FIG. 2, there are all together 8 indicator units 16 and 8 sensor elements 18 in sequence. Wherein, the control circuit 20 receives the signal sent back from each of the sensor elements 18, and after processing and determination, it activates the corresponding indicator unit 16, to avoid the error of triggering a plurality of sensor elements 18 at the same time.

Summing up the above, when taking a ride in an elevator, according to the design of the present invention, the sensor element 18 and control circuit 20 are used to detect the movement of a hand. So, all the user has to do is to point his finger to the control panel 14, then the control matrix of the sensor element 18 on the control panel 14 detects the distance information of an object 12. Since sizes of palms of different persons vary, thus when a user points his finger, the rest of the fingers will form naturally into a fist shape, such that a single object 12 will present different distance information d1˜d8, for the control matrix of the sensor elements 18 to detect. Or alternatively, when a plurality of users point a finger at the same time, then the plurality of objects 12 will present different distance information d1˜d8, for the control matrix of the sensor elements 18 to detect. Wherein, the technical concepts of a single object 12 and a plurality of objects 12 having different distance information d1˜d8 are the same.

Then, as shown in FIG. 2, when the user's finger getting close to the indicator unit 167 and sensor element 187, the sensor elements 181˜188 are able to detect an object at the same time, to calculate the distance information d1˜d8 of the object 12. Upon determining by the control circuit 20 that distance information d7 is the minimum value of the distance information d1˜d8, the control circuit 20 transmits a control signal to the corresponding indicator unit 167, to display the related indication, and control the controlled unit 22 to act. Therefore, the user does not need to actually touch the switch, to achieve triggering the sensor element 18, as such solving the problem of disease contagion for people working in public places. It can also solve the problem of gradual deterioration of contact type switch sensitivity after long period of usage and pressing.

Furthermore, in the embodiment mentioned above, the application of the non-contact type switch control device to the elevator is described. However, the present invention is not limited to this. According to the design of the present invention, the non-contact type switch control device 10 is also applicable to TV station selection. The structure and element connections of the TV station selector are the same as those of the first embodiment, thus it will not be repeated here for brevity. The only difference is that when it is used to control the TV station selection, the controlled unit 22 is a TV station selector.

In the non-contact type switch control device 10 mentioned above, the indicator unit 16 is an incandescent light or an LED element, the sensor element 18 is a magnetic induction proximity switch or an infrared proximity switch, and the control circuit 20 is a central processing unit, a microprocessor, or a single chip microcomputer.

In addition, in order to fully explain the characteristics of the present invention, the 8 indictor units 161˜168 and 8 sensor elements 181˜188 in FIGS. 1 and 2 are used to explain the design concept of the present invention. However, the design concept of the present invention is not limited to this. The number of indicator units 16 and sensor elements 18 can be varied depending on actual requirements. The difference of numbers does not affect the design concept of the present invention.

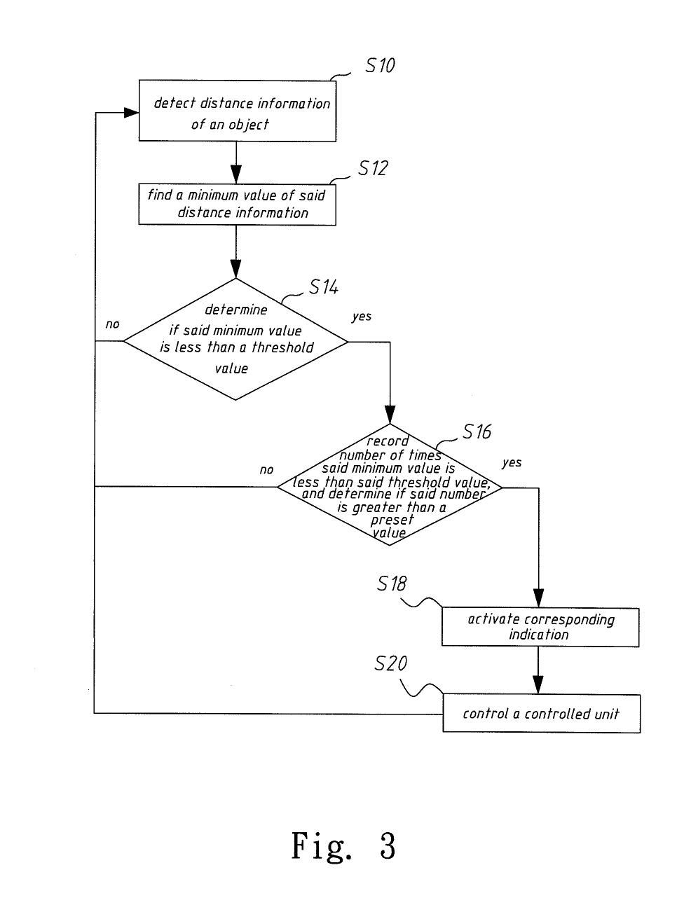

Subsequently, refer to FIG. 3 for a flowchart of the steps of a non-contact type switch control method according to a first embodiment of the present invention. Also, refer to FIGS. 1 and 2 at the same time. As shown in the drawings, the non-contact type switch control method is used to detect an object 12, including the following steps. Firstly, as shown in step S10, the sensor element 18 detects the distance information d1˜d8 of an object 12, and transmits them back to the control circuit 20. Next, as shown in step S12, the control circuit 20 finds out the minimum value of the distance information d1˜d8. Then, in step S14, the control circuit 20 determines if the minimum value of the distance information d1˜d8 is less than a threshold value. If the answer is negative, return to step S10, otherwise perform step S16, the control circuit 20 counts and records the number of times the minimum value is less than the threshold value, then it determines if this number is greater than a preset value. If the answer is negative, return to step S10, otherwise perform step S18, activate the corresponding indication. Finally, perform step S20, to control the controlled unit 22, and return to step S10.

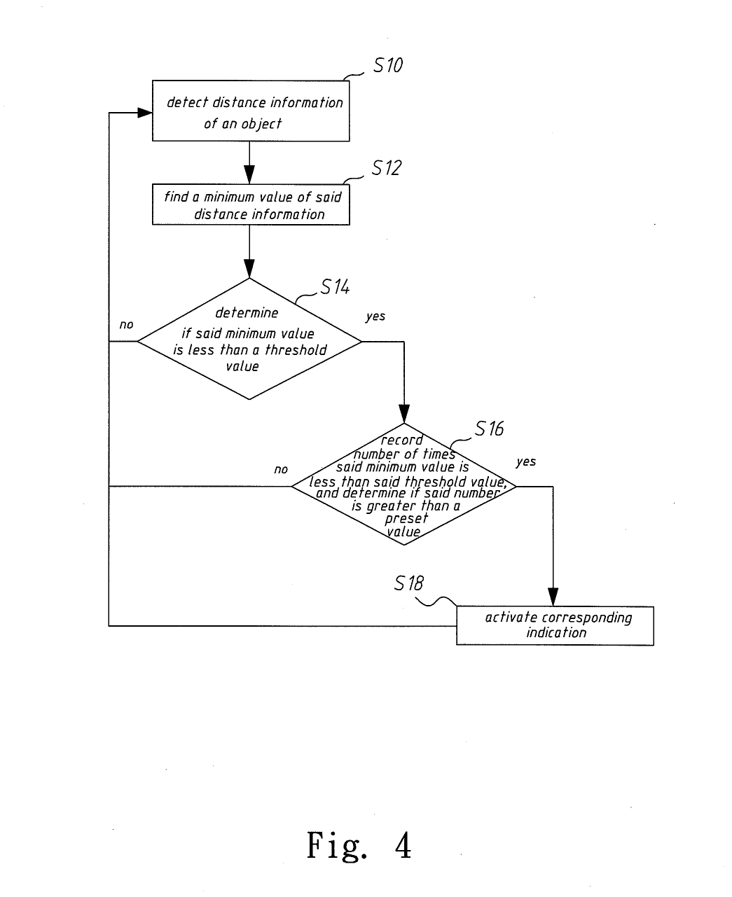

Then, refer to FIG. 4 for a flowchart of the steps of a non-contact type switch control method according to a second embodiment of the present invention. Meanwhile, refer to FIGS. 1, 2, and 3. As shown in the drawings, when applying the first embodiment mentioned above to the condition requiring only the indicator unit 16 to indicate, without the need to control the controlled unit 22, such as a user controlling a signal lamp, then that is the control method of the second embodiment, and that utilizes the same steps as in the first embodiment, thus that will not be repeated herein for brevity. As such, the difference between the second and the first embodiment is that, in the second embodiment, there is no need to proceed to step S20 to control the controlled unit 22. It only requires to proceed to step S18 to activate the corresponding indication, and then return to step S10, to complete an entire second embodiment.

In addition, the control methods of the first and second embodiments mentioned above are methods using the non-contact type switch control device 10 to detect a single object 12. However, the present invention is not limited to this.

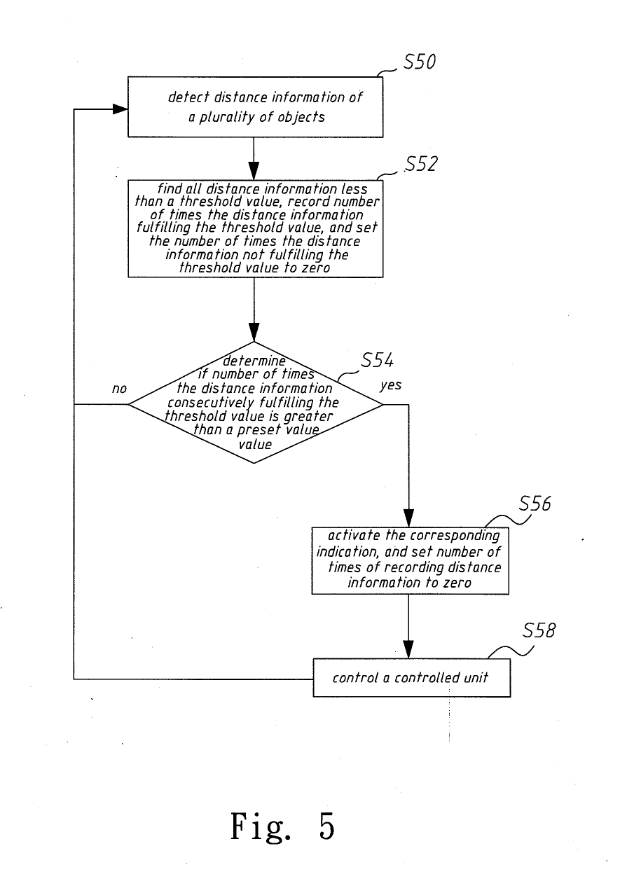

Then, refer to FIG. 5 for a flowchart of the steps of a non-contact type switch control method according to a third embodiment of the present invention, meanwhile, refer to FIGS. 1 and 2 at the same time. As shown in the drawings, the control method of this embodiment can be used to sense a plurality of objects 12, including the following steps. Firstly, as shown in step S50, the sensor element 18 detects the distance information d1˜d8 of a plurality of objects 12, and transmits them back to the control circuit 20. Next, as shown in step S52, the control circuit 20 finds out all the distance information d1˜d8 with its value less than the threshold value, and records the number of times the distance information d1˜d8 fulfilling a threshold value. The control circuit 20 sets the number of times the distance information d1˜d8 not fulfilling the threshold value to zero. Then, in step S54, the control circuit 20 determines if the number of times the distance information d1˜d8 consecutively fulfilling the threshold value is greater than a preset value. In case the answer is negative, return to step S50, otherwise perform step S56, activate the corresponding indication, and set the number of times of recording distance information d1˜d8 to zero. Finally, perform step S58, perform control of the controlled unit 22, then return to step S50.

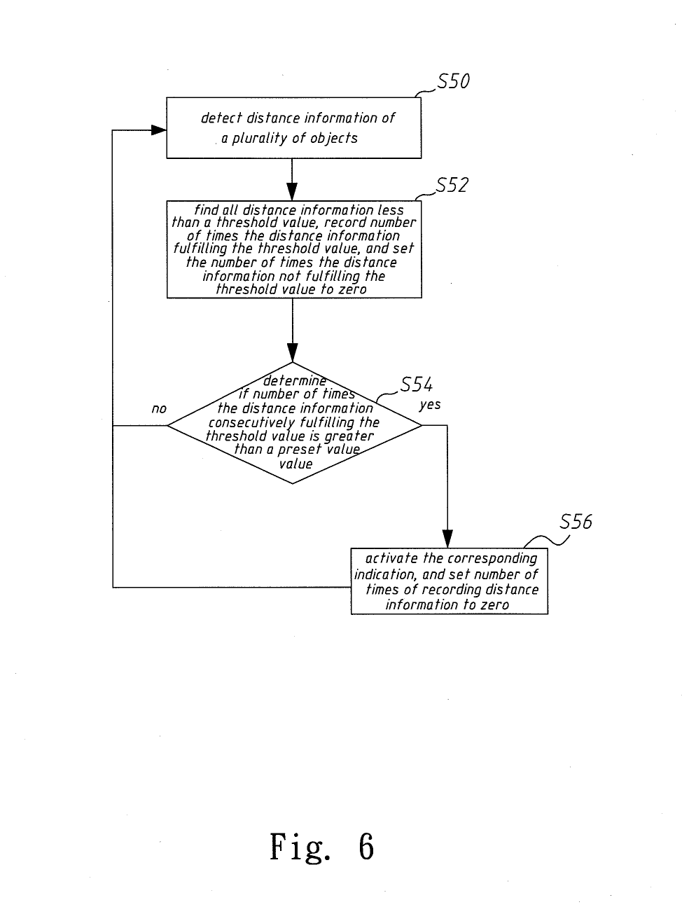

Then, refer to FIG. 6 for a flowchart of the steps of a non-contact type switch control method according to a fourth embodiment of the present invention;

meanwhile, refer to FIGS. 1, 2, and 5. As shown in the drawings, when applying the third embodiment mentioned above to the condition requiring only the indicator unit 16 to indicate, without the need to control the controlled unit 22, such as a user controlling a signal lamp, then that is the control method of the fourth embodiment, and that utilizes the same steps as in the third embodiment, thus that will not be repeated herein for brevity. The difference between the fourth and the third embodiments is that, in the fourth embodiment, there is no need to proceed to step S58 to control the controlled unit 22. It only requires to proceed to step S56 to activate the corresponding indication, and set the number of times of recording the distance information d1˜d8 to zero. then return to step S50, to complete an entire fourth embodiment.

In the descriptions mentioned above, the non-contact type switch control methods of the first embodiment, the second embodiment, the third embodiment, and the fourth embodiment are applied to the elevator control or the signal lamp control. As such, the object 12 is finger or palm of a person, while the threshold value of the effective sensing range is set to 2 cm.

Moreover, for the non-contact type switch control methods of the first embodiment and the second embodiment, in step S18, the control circuit 20 transmits a control signal to the corresponding indicator unit 16 to display the related indication. While, for the non-contact type switch control methods of the third embodiment and the fourth embodiment, in step S56, the control circuit 20 transmits a control signal to the corresponding indicator unit 16 to display the related indication. Wherein, the indicator unit 16 is an incandescent light or an LED element, the sensor element 18 is a magnetic induction proximity switch or an infrared proximity switch, and the control circuit 20 is a central processing unit, a microprocessor, or a single chip microcomputer, and the controlled unit 22 is a motor or TV station selector.

Furthermore, in the non-contact type switch control methods of the first, second, third, and the fourth embodiments, the preset value is set by the engineer. By way of example, in the control methods of the first and second embodiments, when the preset value is set at 3 times, and when the number of times that the minimum value of distance information d1˜d8 less than the threshold value is greater than 3, the control circuit 20 activates the corresponding indication, and/or perform control of the controlled unit 22 at the same time. By way of another example, in the control methods of the third and fourth embodiments, when the preset value is set at 3 times, then the control circuit 20 determines if the number of times the distance information d1˜d8 consecutively fulfilling the threshold value is greater than 3. In case the answer is positive, the control circuit 20 activates the corresponding indication, and/or perform control of the controlled unit 22 at the same time.

Moreover, in the control methods of the first, second, third, and fourth embodiments of the present invention, the preset value of number of times can be calculated by the control circuit 20. For example, in the control methods of the first and second embodiments, when the preset value is set at 3 times, and the interval between the set times is 1 second, so that when the minimum value of the distance information d1˜d8 less than the threshold value is less than 3 times, it can be calculated that the sensing duration of the sensor element 18 is 3 seconds. Or, in the control methods of the third and fourth embodiments, when the preset value is set at 3 times, and the interval between the set times is 1 second, then the number of times the distance information d1˜d8 consecutively fulfilling the threshold value is greater than 3, thus it can be calculated that the detection duration of the sensor element 18 is 3 seconds.

Summing up the above, the present invention provides a non-contact type switch control device, and through the control method thereof, the sensor element may perform detection of distance information for a single object or a plurality of objects. Upon receiving and determining the distance information, the control circuit activates the corresponding indication. Therefore, a user does not need to actually touch the switch to achieve triggering by the sensor element, as such solving the problem that people working in the public places are liable to be inflicted by contagious diseases through contact. In addition, it can solve the problem that the sensitivity of contact type switch tends to deteriorate gradually due to long period usage and pressing.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A non-contact type switch control device, used to detect one or a plurality of objects, including;
a control panel, on which is provided with a plurality of indicator units a plurality of sensor elements, disposed on said control panel, each said sensor element detects distance information of an object; and
a control circuit, connected electrically to a controlled unit, said indicator units, and said sensor elements, to receive and determine said distance information, and then transmit a control signal to said corresponding indicator unit, to display related indication, such that said control circuit controls action of said controlled unit.

2. The non-contact type switch control device as claimed in claim 1, wherein said controlled unit is a motor or a station selector.

3. The non-contact type switch control device as claimed in claim 1, wherein on each said sensor element is disposed each said corresponding indicator unit, said sensor elements and said indicator units are arranged into a control matrix.

4. The non-contact type switch control device as claimed in claim 3, wherein said indicator unit is an incandescent light or an LED element, said sensor element is a magnetic induction proximity switch or an infrared proximity switch, and said control circuit is a central processing unit, a microprocessor, or a single chip microcomputer.

5. A non-contact type switch control method, used to detect an object, including following steps:
(a) detect distance information of said object;
(b) find a minimum value of said distance information;
(c) determine if said minimum value of said distance information is less than a threshold value, if answer is negative, return to step (a), otherwise perform step (d);
(d) record number of times said minimum value is less than said threshold value, then determine if said number is less than a preset value, if answer is negative, return to step (a), otherwise perform step (e); and
(e) activate corresponding indication.

6. The non-contact type switch control method as claimed in claim 5, further comprising a step of :
(f) performing control of a controlled unit, and then return to step (a).

7. The non-contact type switch control method as claimed in claim 6, wherein said controlled unit is a motor or a station selector.

8. The non-contact type switch control method as claimed in claim 5, wherein in said step (a), a sensor element detects said distance information of said object.

9. The non-contact type switch control method as claimed in claim 8, wherein said sensor element is a magnetic induction proximity switch or an infrared proximity switch.

10. The non-contact type switch control method as claimed in claim 5, wherein in said step (e), a control circuit sends a control signal to a corresponding indicator unit, to display related indication.

11. The non-contact type switch control method as claimed in claim 10, wherein said control circuit is a central processing unit, a microprocessor, or a single chip microcomputer.

12. The non-contact type switch control method as claimed in claim 10, wherein said indicator unit is an incandescent light or an LED element.

13. A non-contact type switch control method, used to detect a plurality of objects, including following steps:
(a) detect distance information of said objects;
(b) find said distance information of said objects less than a threshold value, record number of times said distance information fulfilling said threshold value, and set said number of times said distance information not fulfilling said threshold value to zero;
(c) determine if said number of times said distance information consecutively fulfilling said threshold value is greater than a preset value, in case the answer is negative, return to the step (a), otherwise perform step (d); and
(d) activate corresponding indication, and set said number of times of recording said distance information to zero.

14. The non-contact type switch control method as claimed in claim 13, further comprising a step of:
(e) performing control of a controlled unit, and return to step (a).

15. The non-contact type switch control method as claimed in claim 14, wherein said controlled unit is a motor or a station selector.

16. The non-contact type switch control method as claimed in claim 13, wherein in said step (a), a sensor element detects said distance information of said object.

17. The non-contact type switch control method as claimed in claim 16, wherein said sensor element is a magnetic induction proximity switch or an infrared proximity switch.

18. The non-contact type switch control method as claimed in claim 13, wherein in said step (d), a control circuit sends a control signal to a corresponding indicator unit, to display related indication.

19. The non-contact type switch control method as claimed in claim 18, wherein said control circuit is a central processing unit, a microprocessor, or a single chip microcomputer.

20. The non-contact type switch control method as claimed in claim 18, wherein said indicator unit is an incandescent light or an LED element.
